(19) United States
(12) Patent Application Publication
(10) Pub. No.: US 2025/0366290 A1
(43) Pub. Date: Nov. 27, 2025

(54) DISPLAY DEVICE AND METHOD FOR MANUFACTURING THE SAME

(71) Applicant: SAMSUNG DISPLAY CO., LTD., YONGIN-SI (KR)

(72) Inventors: Hyun Eok SHIN, Yongin-si (KR); Gwang Geun LEE, Yongin-si (KR); In Young JUNG, Yongin-si (KR)

(21) Appl. No.: 19/188,379

(22) Filed: Apr. 24, 2025

(30) Foreign Application Priority Data
May 24, 2024 (KR) 10-2024-0067821

(51) Int. Cl. H10H 29/39; H10H 29/01; H10H 29/80

(52) U.S. Cl. CPC H10H 29/39; H10H 29/012; H10H 29/8321

(57) ABSTRACT

A display device includes a pixel electrode and a common electrode disposed on a substrate. An organic layer is disposed on the pixel electrode and the common electrode. A light emitting element is disposed on the organic layer and includes a semiconductor stack and a first and second contact electrode. A first connection electrode connects the first contact electrode and the pixel electrode. A second connection electrode connects the second contact electrode and the common electrode. First and second side electrodes are disposed on a side of the light emitting element and a top surface of the connection electrodes. First and second slope inclined layers are disposed on a side surface of the side electrodes and a second slope inclined layer. The side electrodes have downwardly concave structures between the side surface of the light emitting element and the slope inclined layer.

### CROSS-REFERENCE TO RELATED APPLICATION

The present application claims priority to Korean Patent Application No. 10-2024-0067821, filed on May 24, 2024, in the Korean Intellectual Property Office (KIPO), the entire disclosure of which is herein incorporated by reference.

### TECHNICAL FIELD

The present disclosure relates to a display device and, more specifically, to a display device with side electrodes on light emitting elements and a method for manufacturing the same.

### DISCUSSION OF THE RELATED ART

As the information society develops, the demand for display devices for displaying images is increasing in various forms. The display device may be a flat panel display such as a liquid crystal display, a field emission display, a light emitting display, and the like.

The light emitting display device may include an organic light emitting diode display device including an organic light emitting diode (OLED) element as a light emitting element, and a micro light emitting display device including a micro light emitting diode element (hereinafter referred to as a micro light emitting diode element) as a light emitting element. Since the micro light emitting diode element is made of inorganic materials, it may experience less deterioration and a longer lifespan compared to an organic light emitting diode element.

### SUMMARY

A display device includes a substrate. A pixel electrode and a common electrode are disposed on the substrate. An organic layer is disposed on the pixel electrode and the common electrode. A light emitting element is disposed on the organic layer and includes a semiconductor stack, a first contact electrode, and a second contact electrode. The first and second contact electrodes are disposed on one surface of the semiconductor stack. A first connection electrode id connected to the first contact electrode and the pixel electrode. A second connection electrode is connected to the second contact electrode and the common electrode. A first side electrode is disposed on a first side of the light emitting element and a top surface of the first connection electrode. A second side electrode is disposed on a second side of the light emitting element and a top surface of the second connection electrode. A first slope inclined layer is disposed on a side surface of the first side electrode. A second slope inclined layer is disposed on a side surface of the second side electrode. The first side electrode and the second side electrode have a downwardly concave structure between the first side of the light emitting element and the first slope inclined layer and between the second side of the light emitting element and the second slope inclined layer.

A method of manufacturing a display device includes transferring light emitting elements including a first contact electrode and a second contact electrode disposed on one surface of a semiconductor stack onto a first connection electrode and a second connection electrode of a substrate. An electrode material layer and an insulating material layer are sequentially formed on a first connection electrode and a second connection electrode, in regions thereof where said light emitting elements are not disposed and are exposed. A first slope inclined layer and a second slope inclined layer are formed on a side surface of the light emitting elements by etching the insulating material layer. The electrode material layer is etched to form a first side electrode and a second side electrode. The first side electrode and the second side electrode have a structure in which the first side electrode and the second side electrode are concave downward between a side surface of the light emitting elements and the first and second slope inclined layers.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment.

FIG. 2 is a layout view of the display device according to the embodiment.

FIG. 3 is a block diagram of the display device according to the embodiment.

FIG. 4 is an equivalent circuit diagram of a subpixel according to an embodiment.

FIG. 5 is a layout diagram illustrating pixels of a display area according to one embodiment.

FIG. 6 is a cross-sectional view illustrating an example cross-section of one display panel corresponding to lines I1-I1′ in FIG. 5.

FIG. 7 is a cross-sectional view illustrating an example of area A1 in FIG. 6 in detail.

FIG. 8 is a cross-sectional view illustrating an example of area A1 in FIG. 6 in detail.

FIGS. 9 and 10 are cross-sectional views illustrating an example of area A1 in FIG. 6 in detail.

FIG. 11 is a detailed cross-sectional view illustrating an example of area A1 in FIG. 6.

FIG. 12 is a flowchart illustrating a method of manufacturing a display device according to one embodiment.

FIGS. 13 to 17 are cross-sectional diagrams illustrating a method of manufacturing a display device according to one embodiment.

FIGS. 18 to 20 are cross-sectional diagrams illustrating a method of manufacturing a display device according to one embodiment.

FIG. 21 is a perspective diagram illustrating a method of manufacturing a display device according to one embodiment.

FIGS. 22 to 24 are cross-sectional diagrams illustrating a method of manufacturing a display device according to one embodiment.

FIG. 25 is a perspective diagram illustrating a smart watch including a display device according to one embodiment.

FIG. 26 is a perspective diagram illustrating a virtual reality device including a display device according to one embodiment.

FIG. 27 is an exploded view illustrating a virtual reality device including a display device according to one embodiment.

FIG. 28 is a perspective diagram illustrating a virtual reality device including a display device according to an embodiment.

FIG. 29 is a perspective diagram illustrating an automotive instrument panel and center fascia including display devices according to one embodiment.

FIG. 30 is a perspective diagram illustrating a transparent display device including a display device according to one embodiment.

### DETAILED DESCRIPTION

The embodiments will now be described more fully hereinafter with reference to the accompanying drawings. The embodiments may, however, be provided in different forms and should not necessarily be construed as limiting. The same reference numbers may indicate the same components throughout the disclosure and the drawings. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Some of the parts which are not associated with the description might not be provided in order to better describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not necessarily be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Hereinafter, specific embodiments will be described with reference to the accompanying drawings.

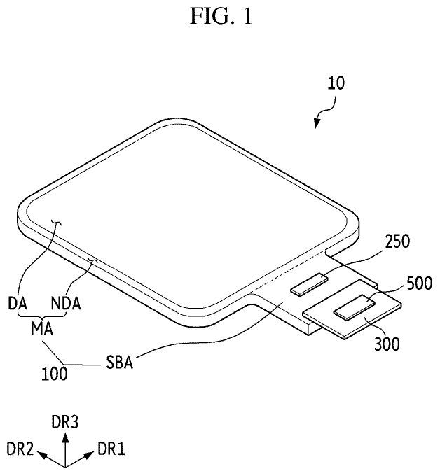

FIG. 1 is a perspective view of a display device 10 according to an embodiment.

Referring to FIG. 1, the display device 10 is a device for displaying moving images and/or still images. The display device 10 may be used as a display screen in portable electronic devices such as mobile phones, smartphones, tablet computers, smart watches, watch phones, mobile communication terminals, electronic notebooks, electronic books, portable multimedia players (PMPs), navigation devices, and ultra-mobile PCs (UMPCs), as well as in various products such as televisions, notebook computers, computer monitors, digital billboards, and Internet of things (IoT) devices.

The display device 10 may be a light emitting display such as an organic light emitting diode display using an organic light emitting diode, a quantum dot light emitting display including a quantum dot light emitting layer, an inorganic light emitting display including an inorganic semiconductor, or a micro- or nano-light emitting display using a micro- or nano-light emitting diode (LED). A case where the display device 10 is a micro- or nano-light emitting display will be mainly described below, but the present disclosure is not necessarily limited thereto. For ease of description, a micro- or nano-LED will be referred to as a light emitting element.

The display device 10 includes a display panel 100, a display driving circuit 250, a circuit board 300, and a power supply unit 500.

The display panel 100 may be shaped like a rectangle having a pair of short sides extending in a first direction DR1 and a pair of long sides extending in a second direction DR2 intersecting the first direction DR1. Each corner where a short side extending in the first direction DR1 meets a long side extending in the second direction DR2 may be rounded to have a predetermined curvature (thereby forming a rounded-rectangle shape) or may be right-angled (thereby forming an ordinary rectangle). The planar shape of the display panel 100 is not necessarily limited to a quadrangular shape but may also be other polygonal shapes, a circular shape, or an elliptical shape. The display panel 100 may be formed flat, but embodiments are not necessarily limited thereto. For example, the display panel 100 may include a curved portion formed at left and right ends and having a constant or varying curvature. In addition, the display panel 100 may be formed to be flexible so that it can be curved, bent, folded, or rolled to a noticeable extent without cracking or otherwise sustaining damage.

A substrate SUB of the display panel 100 may include a main area MA and a sub-area SBA.

The main area MA may include a display area DA which displays an image and a non-display area NDA disposed around the display area DA (e.g., so as to surround the display area DA on at least two sides thereof or so as to be proximate to only one side thereof). The display area DA may include a plurality of pixels which display an image. Each of the pixels may include a plurality of subpixels. For example, each of the pixels may include a first subpixel which emits light of a first color, a second subpixel which emits light of a second color, and a third subpixel which emits light of a third color, but embodiments of the present specification are not necessarily limited thereto.

The sub-area SBA may protrude from a side of the main area MA in the second direction DR2. Although the sub-area SBA is illustrated as being unfolded in FIG. 1, it may be bent. In this case, the sub-area SBA may be placed on a lower surface of the display panel 100. When the sub-area SBA is bent, it may be overlapped by the main area MA in a third direction DR3 which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit and attached onto the display panel 100 using a chip on glass (COG) method, a chip on plastic (COP) method, or an ultrasonic bonding method. However, embodiments are not necessarily limited thereto. For example, the display driving circuit 250 may also be attached onto the circuit board 300 using a chip on film (COF) method.

The circuit board 300 may be attached to an end of the sub-area SBA of the display panel 100. Accordingly, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board, a printed circuit board, or a flexible film such as a chip on film.

The power supply unit 500 may generate a plurality of panel driving voltages according to a power supply voltage from the outside. The power supply unit 500 may be formed as an integrated circuit and attached onto the circuit board 300 using a COF method.

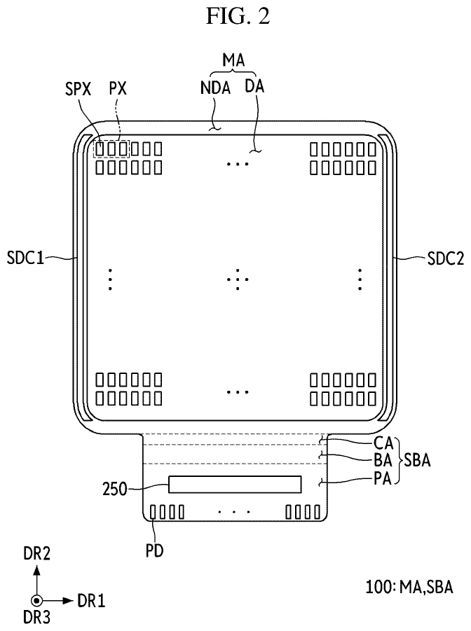

FIG. 2 is a layout view of the display device 10 according to an embodiment. FIG. 2 illustrates a state in which the sub-area SBA is unfolded without being bent.

Referring to FIG. 2, the display panel 100 may include the main area MA and the sub-area SBA.

The main area MA may include the display area DA which displays an image and the non-display area NDA disposed around the display area DA. The display area DA may occupy most of the main area MA. The display area DA may be disposed in a center of the main area MA.

The display area DA may include a plurality of pixels PX for displaying an image, and each of the pixels PX may include a plurality of subpixels SPX. A pixel PX may be defined as a smallest subpixel group that can express any desired color and brightness.

The non-display area NDA may neighbor the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be disposed in the non-display area NDA. The first scan driver SDC1 may be disposed on a side (e.g., a left side) of the display panel 100, and the second scan driver SDC2 may be disposed on the other side (e.g., a right side) of the display panel 100. However, embodiments of the present specification are not necessarily limited thereto.

Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output the scan signals to scan lines.

The sub-area SBA may protrude from a side of the main area MA in the second direction DR2. A length of the sub-area SBA in the second direction DR2 may be smaller than a length of the main area MA in the second direction DR2. A length of the sub-area SBA in the first direction DR1 may be smaller than a length of the main area MA in the first direction DR1 or may be substantially equal to the length of the main area MA in the first direction DR1. The sub-area SBA may be bent and placed under the display panel 100. In this case, the sub-area SBA may be overlapped by the main area MA in the third direction DR3.

The sub-area SBA may include a connection area CA, a pad area PA, and a bending area BA.

The connection area CA is an area protruding from a side of the main area MA in the second direction DR2. A side of the connection area CA may contact the non-display area NDA of the main area MA, and the other side of the connection area CA may contact the bending area BA.

The pad area PA is an area where pads PD and the display driving circuit 250 are disposed. The display driving circuit 250 may be attached to driving pads of the pad area PA using a conductive adhesive such as an anisotropic conductive film. The circuit board 300 may be attached to the pads PD of the pad area PA using a conductive adhesive such as an anisotropic conductive film. A side of the pad area PA may contact the bending area BA.

The bending area BA is a bendable area. When the bending area BA is bent, the pad area PA may be placed under the connection area CA and the main area MA. The bending area BA may be disposed between the connection area CA and the pad area PA. A side of the bending area BA may contact the connection area CA, and the other side of the bending area BA may contact the pad area PA.

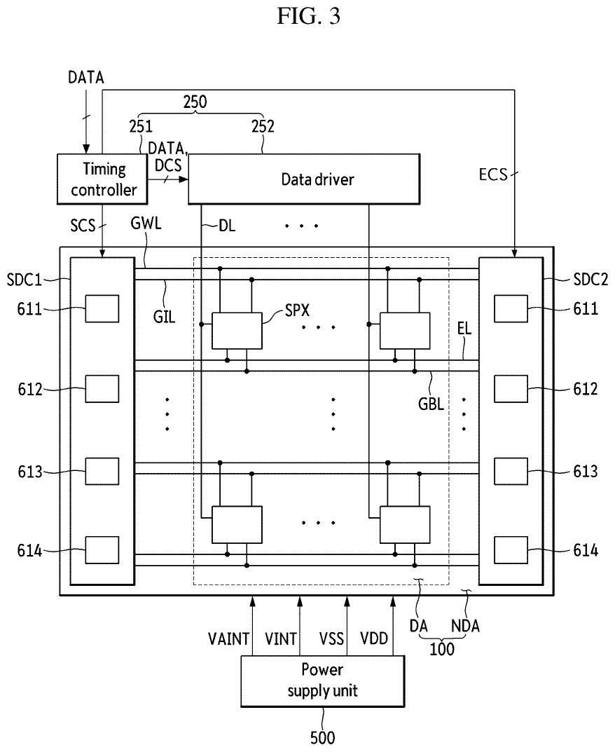

FIG. 3 is a block diagram of the display device 10 according to an embodiment.

Referring to FIG. 3, the display area DA includes a plurality of pixels PX, a plurality of scan lines SL, a plurality of emission control lines EL, and a plurality of data lines DL.

The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1. The scan lines SL include a plurality of write scan lines GWL, a plurality of control scan lines GCL, a plurality of initialization scan lines GIL, and a plurality of bias scan lines GBL.

Each of the subpixels SPX may be connected to any one of the write scan lines GWL, any one of the control scan lines GCL, any one of the initialization scan lines GIL, any one of the bias scan lines GBL, any one of the emission control lines EL, and any one of the data lines DL. Each of the subpixels SPX may receive a data voltage of a data line DL according to a write scan signal of a write scan line GWL and may emit light from a light emitting element according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, and a bias scan signal output unit 613 and the emission signal output unit 614. Each of the write scan signal output unit 611, the initialization scan signal output unit 612, the bias scan signal output unit 613, and the emission signal output unit 614 may receive a scan timing control signal SCS from a timing controller 251.

The write scan signal output unit 611 may generate write scan signals according to the scan timing control signal SCS of the timing controller 251 and sequentially output the write scan signals to the write scan lines GWL.

The initialization scan signal output unit 612 may generate initialization scan signals according to the scan timing control signal SCS and sequentially output the initialization scan signals to the initialization scan lines GIL. The bias scan signal output unit 613 may generate bias scan signals according to the scan timing control signal SCS and sequentially output the bias scan signals to the bias scan lines GBL. The emission signal output unit 614 may generate emission control signals according to the scan timing control signal SCS and sequentially output the emission control signals to the emission control lines EL.

The display driving circuit 250 includes the timing controller 251 and a data driver 252.

The data driver 252 may receive digital video data DATA and a data timing control signal DCS from the timing controller 251. The data driver 252 converts the digital video data DATA into analog data voltages according to the data timing control signal DCS and outputs the analog data voltages to the data lines DL. In this case, subpixels SPX may be selected by write scan signals of the first scan driver SDC1 and the second scan driver SDC2, and the data voltages may be supplied to the selected subpixels SPX.

The timing controller 251 may receive the digital video data DATA and timing signals from an eternal source. The timing controller 251 may generate the scan timing control signal SCS and the data timing control signal DCS for controlling the display panel 100 according to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power supply voltage from the outside. For example, the power supply unit 500 may generate a first driving voltage VDD, a second driving voltage VSS and a third driving voltage VINT and supply them to the display panel 100.

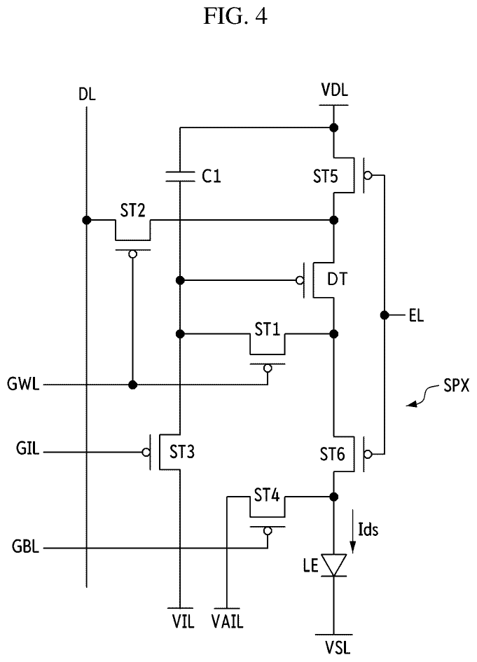

FIG. 4 is an equivalent circuit diagram of a subpixel SPX according to an embodiment.

Referring to FIG. 4, the subpixel SPX, according to the embodiment, may be connected to scan lines GWL, GIL, GCL and GBL, an emission control line EL, and a data line DL. For example, the subpixel SPX may be connected to a write scan line GWL, an initialization scan line GIL, a control scan line, a bias scan line GBL, the emission line EL, and the data line DL.

The subpixel SPX, according to the embodiment, includes a driving transistor DT, switch elements, a capacitor C1, and a light emitting element LE. The switch elements include first through sixth transistors ST1 through ST6.

The driving transistor DT includes a gate electrode, a conductive layer, and a second electrode. The driving transistor DT controls a drain-source current Ids (hereinafter, referred to as a “driving current”) flowing between the conductive layer and the second electrode according to a data voltage applied to the gate electrode.

The light emitting element LE may be a micro-LED.

The light emitting element LE emits light according to the driving current Ids. The amount of light emitted from the light emitting element LE may be proportional to the driving current Ids. An anode of the light emitting element LE may be connected to a conductive layer of the fourth transistor ST4 and a second electrode of the sixth transistor ST6, and a cathode may be connected to a second power line VSL to which a second power supply voltage is applied.

The capacitor C1 is formed between the second electrode of the driving transistor DT and a first power line VDL to which a first power supply voltage is applied. The first power supply voltage may be at a higher level than the second power supply voltage. One electrode of the capacitor C1 may be connected to the second electrode of the driving transistor DT, and the other electrode may be connected to the first power line VDL.

As illustrated in FIG. 4, the first through sixth transistors ST1 through ST6 and the driving transistor DT may all be formed as p-type metal-oxide-semiconductor field effect transistors (MOSFETs). In this case, an active layer of each of the first through sixth transistors ST1 through ST6 and the driving transistor DT may be made of polysilicon.

A gate electrode of the first transistor ST1 and a gate electrode of the second transistor ST2 may be connected to the write scan line GWL, a gate electrode of the third transistor ST3 may be connected to the initialization scan line GIL, and a gate electrode of the fourth transistor ST4 may be connected to the bias scan line GBL. Since the first through sixth transistors ST1 through ST6 are formed as p-type MOSFETs, they may be turned on when a scan signal of a gate-low voltage and an emission control signal are transmitted to the control scan line GCL, the initialization scan line GIL, the write scan line GWL, the bias scan line GBL, and the emission line EL. One electrode of the third transistor ST3 and one electrode of the fourth transistor ST4 may be connected to an initialization voltage line VIL.

Alternatively, the driving transistor DT, the second transistor ST2, the fourth transistor ST4, the fifth transistor ST5 and the sixth transistor ST6 may be formed as p-type MOSFETs, and the first transistor ST1 and the third transistor ST3 may be formed as n-type MOSFETs. The active layer of each of the driving transistor DT, the second transistor ST2, the fourth transistor ST4, the fifth transistor ST5 and the sixth transistor ST6 formed as p-type MOSFETs may be made of polysilicon, and the active layer of each of the first transistor ST1 and the third transistor ST3 formed as n-type MOSFETs may be made of an oxide semiconductor.

In this case, since the first transistor ST1 and the third transistor ST3 are formed as n-type MOSFETs, the first transistor ST1 may be turned on in response to a scan signal of a gate-high voltage, and the third transistor ST3 may be turned on in response to an initialization scan signal of a gate-high voltage. On the other hand, since the second transistor ST2, the fourth transistor ST4, the fifth transistor ST5 and the sixth transistor ST6 are formed as p-type MOSFETS, they may be turned on in response to a scan signal of a gate-low voltage and an emission control signal.

Alternatively, the fourth transistor ST4 may be formed as an n-type MOSFET. In this case, the active layer of the fourth transistor ST4 may be made of an oxide semiconductor. When the fourth transistor ST4 is formed as an n-type MOSFET, it may be turned on in response to a scan signal of a gate-high voltage.

Alternatively, the first through sixth transistors ST1 through ST6 and the driving transistor DT may all be formed as n-type MOSFETs. In this case, the active layer of each of the first through sixth transistors ST1 through ST6 and the driving transistor DT may be made of an oxide semiconductor.

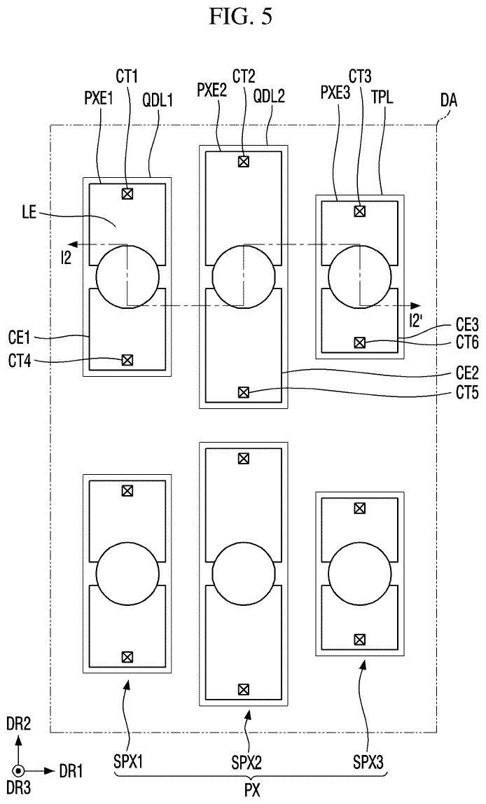

FIG. 5 is a layout diagram illustrating pixels of a display area according to one embodiment.

Referring to FIG. 5, each of the plurality of pixels PX of the display area DA may include three sub-pixels SPX1, SPX2, and SPX3, but the embodiment of the present disclosure is not necessarily limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may each be capable of displaying a single color.

The plurality of pixels PX may be arranged in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. For example, the fourth color light may be white light.

The first sub-pixel SPX1 includes a first pixel electrode PXE1, a plurality of light emitting elements LE, and a first light conversion layer QDL1. The second sub-pixel SPX2 includes a second pixel electrode PXE2, the plurality of light emitting elements LE, and the second light conversion layer QDL2. The third sub-pixel SPX3 includes a third pixel electrode PXE3, a plurality of light emitting elements LE, and a third light conversion layer QDL3.

In each of the first sub-pixel SPX1, the second sub-pixel SPX2, and the third sub-pixel SPX3, the pixel electrodes PXE1, PXE2, and PXE3 and the common electrodes CE1, CE2, and CE3 may be arranged in the second direction DR2. Each of the pixel electrodes PXE1, PXE2, and PXE3 and the common electrodes CE1, CE2, and CE3 may have a rectangular planar shape, but the embodiment of the present disclosure is not necessarily limited thereto. The area of the first pixel electrode PXE1 may be the same as the area of the first common electrode CE1, the area of the second pixel electrode PXE2 may be the same as the area of the second common electrode CE2 and the area of the third pixel electrode PXE3 may be the same as the area of the third common electrode CE3, but embodiments of the present disclosure are not necessarily limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1, and the area of the second common electrode CE2 may be larger than the area of the first common electrode CE1. Also, while the light transmission layer TPL transmits light of the light emitting element LE as it is, the first light conversion layer QDL1 needs to convert the light. Therefore, the area of the first pixel electrode PXE1 may be larger than the area of the third pixel electrode PXE3, and the area of the first common electrode CE1 may be larger than the area of the third common electrode CE3.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The first common electrode CE1 may be connected to the second power supply line VSL to which a second driving voltage VSS is applied through a first common connection hole CT4. The second common electrode CE2 may be connected to the second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrode CE may be referred to as a cathode electrode or a second electrode.

The plurality of light emitting elements LE may be disposed on the pixel electrodes PXE1, PXE2, and PXE3 and the common electrodes CE1, CE2, and CE3. Each of the plurality of light emitting elements LE may have a circular planar shape, but the embodiments of the present disclosure are not necessarily limited thereto. For example, each of the plurality of light emitting elements LE may have a rectangular planar shape.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE of the second pixel electrode PXE2 and the second sub-pixel SPX2. The area of the second light conversion layer QDL2 may be larger than the sum of the areas of the second pixel electrode PXE2 and the second common electrode CE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third pixel electrode PXE3 and the third sub-pixel SPX3. The area of the light transmission layer TPL may be larger than the sum of the areas of the third pixel electrode PXE3 and the third common electrode CE3. For example, the light transmission layer TPL may directly transmit the third light emitted from the plurality of light emitting elements LE of the third sub-pixel SPX3.

When the light emitting element LE of the first sub-pixel SPX1 emits light of the first color, the light emitting element LE of the second sub-pixel SPX2 emits light of the second color, and the light emitting element LE of the third sub-pixel SPX3 emits light of the third color, the light conversion layers QDL1 and QDL2 and the light transmission layer TPL may be omitted.

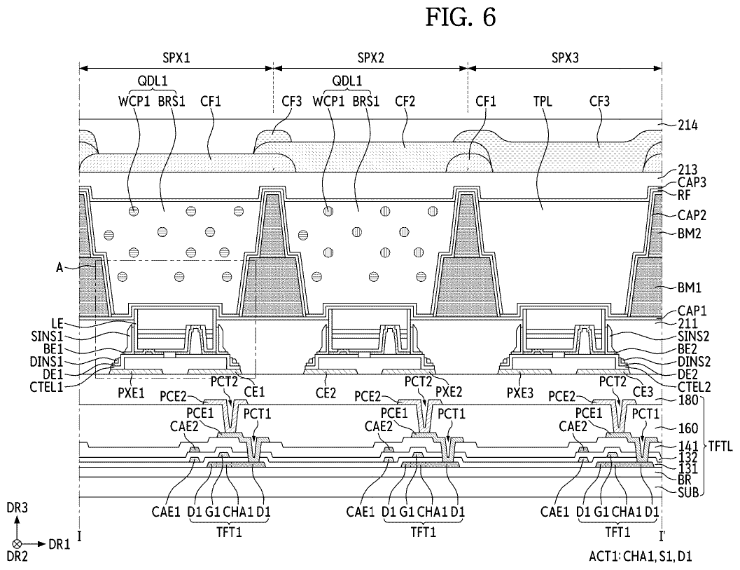

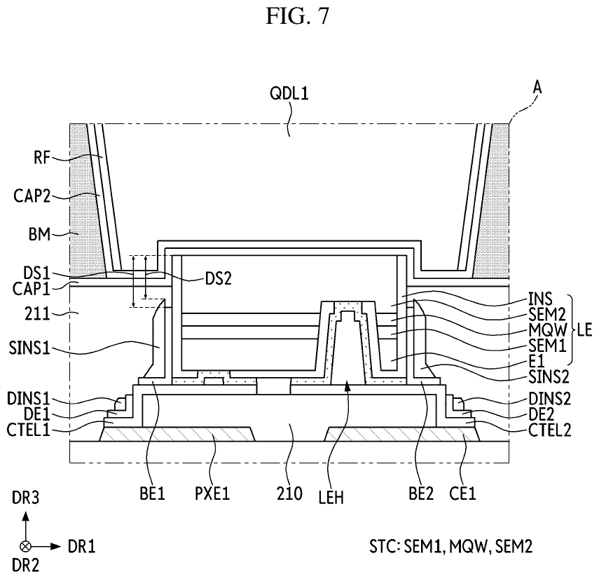

FIG. 6 is a cross-sectional view illustrating an example cross-section of one display panel corresponding to lines 11-11′ in FIG. 5. FIG. 7 is a cross-sectional view illustrating one example of area A1 in FIG. 6 in detail.

Referring to FIGS. 6 and 7, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be disposed on the substrate SUB. The barrier film BR is a film that protects the transistors of the thin film transistor layer TFTL and the light emitting layer 172 of the light emitting element layer EML from moisture penetrating through the substrate SUB, which is vulnerable to moisture penetration. The barrier film BR may be composed of a plurality of inorganic films that are alternately stacked.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1.

A first gate metal layer may be disposed on a first gate insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be disposed apart from each other, but the first gate electrode G1 and the first capacitor electrode CAE1 may be connected to each other.

A second gate insulating film 132 may be disposed on the first gate electrode G1 and the first capacitor electrode CAE1 of the thin film transistor TFT1.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Since the second gate insulating film 132 has a predetermined dielectric constant, the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE 1 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second source contact hole PCT2 penetrating the first planarization organic film 160.

A second planarization organic film 180 may be disposed on the second source connection electrode PCE2.

The barrier film BR, the first gate insulating film 131, the second gate insulating film 132, the third gate insulating film 133, and the interlayer insulating film 141 may be formed from an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may be formed of an organic film such as an acrylic resin, an epoxy resin, a phenolic resin, a polyamide resin, a polyimide resin, or the like.

A light emitting element layer may be disposed on the second planarization organic film 180. The light emitting element layer may include pixel electrodes PXE1, PXE2, PXE3, light emitting elements LE, a common electrode CE, and an organic film 190.

A pixel electrode layer including the pixel electrodes PXE1, PXE2, and PXE3 and the common electrodes CE1, CE2, and CE3 may be disposed on the second planarization organic film 180.

Each of the first pixel electrode PXE1, the second pixel electrode PXE2, and the third pixel electrode PXE3 may be connected to the second source connection electrode PCE2 through a connection hole (CT1, CT2, and CT3 in FIG. 5) penetrating the second planarized organic film 180. Each of the pixel electrodes PXE1, PXE2, and PXE3 may be connected to a first source area S1 or a first drain area D1 of the thin film transistor TFT1 through the first source connection electrode PCE 1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through the common connection hole (CT4, CT5, and CT6 in FIG. 5). The second common electrode CE2 may be connected to the second power supply line (VSL in FIG. 4) through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one of molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) with low sheet resistance to lower the resistance of each of the pixel electrodes PXE1, PXE2, and PXE3.

A first organic layer 210 may be disposed on each pixel electrode layer. The first organic layer 210 serves to temporarily fix or adhere the top layer. For example, the first organic layer 210 may be a film for temporarily adhering a first connection electrode CTEL1 and a second connection electrode CTEL2 to each of the pixel electrodes PXE1, PXE2, and PXE3 and the common electrodes CE1, CE2, and CE3. To facilitate temporary adhesion, the thickness of the first organic layer 210 may be larger than the thickness of each of the pixel electrodes PXE1, PXE2, and PXE3 and the common electrodes CE1, CE2, and CE3 and larger than the thickness of the contact electrode CTE.

The first organic layer 210 may be a photosensitive organic film, such as photoresist. Alternatively, the first organic layer 210 may be formed from an acrylic resin, an epoxy resin, a phenolic resin, a polyamide resin, a polyimide resin, or the like.

The plurality of light emitting elements LE may be disposed on the first connection electrode CTEL1 and the second connection electrode CTEL2. FIGS. 6 and 7 illustrate that the light emitting element LE is a flip-type micro-LED. The flip-type micro-LED refers to an LED in which contact electrodes CTE1 and CTE2 are formed on one side (e.g., the bottom side) of the light emitting element LE.

Each of the plurality of light emitting elements LE may be formed of an inorganic material such as gallium nitride (GaN).

Each of the plurality of light emitting elements LE may be formed by growing on a semiconductor substrate such as a silicon substrate or sapphire substrate. The plurality of light emitting elements LE may be directly transferred from the semiconductor substrate to the pixel electrode layer of the display panel 100. Alternatively, the plurality of light emitting elements LE may be transferred onto the pixel electrodes PXE1, PXE2, and PXE3 of the display panel 100 through an electrostatic method using an electrostatic head or a stamp method using an elastic polymeric material such as PDMS or silicone as a transfer substrate.

The light emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, and a second semiconductor layer SEM2 sequentially arranged in the third direction DR3.

The conductive layer E1 may be disposed on the lower surface of the first semiconductor layer SEM1. Although FIG. 7 illustrates that the conductive layer E1 covers the entire lower surface of the first semiconductor layer SEM1, the embodiments of the present disclosure are not necessarily limited thereto. In one example, the conductive layer E1 may be disposed on a portion of the lower surface of the first semiconductor layer SEM1. The conductive layer E1 may include any one of molybdenum (Mo), aluminum (Al), chromium (Cr), gold (Au), titanium (Ti), nickel (Ni), neodymium (Nd), and copper (Cu).

The first semiconductor layer SEM1 may be disposed on the conductive layer E1. The first semiconductor layer SEM1 may include a semiconductor material layer doped with a first conductive dopant, such as magnesium (M g), zinc (Zn), calcium (Ca), strontium (Sr), barium (Ba), or the like, for example gallium nitride (GaN).

In one embodiment, the first semiconductor layer SEM1 may have a multilayer structure. For example, the first semiconductor layer SEM1 may include a P−GaN layer and a P+GaN layer. The P+GaN layer may be disposed below the P−GaN layer. The P+GaN layer may be a layer overdoped with a first conductivity type dopant. The P+GaN layer may be formed to a thickness of several nanometers or tens of degrees on the top to aid ohmic formation. P+GaN may be useful in lowering the operating voltage by increasing the ohmic characteristics with the top metal through the tunneling effect.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not necessarily limited thereto.

Alternatively, the active layer MQW may have a structure in which semiconductor materials having a high band gap energy and semiconductor materials having a low band gap energy are alternately stacked with each other, may include other Group three to five semiconductor materials according to the wavelength range of emitted light.

For example, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the first semiconductor layer SEM1. The second semiconductor layer SEM2 may be a semiconductor material layer doped with a second conductivity type dopant such as silicon (Si), germanium (Ge), tin (Sn), etc., for example, gallium nitride (GaN).

In one embodiment, the second semiconductor layer SEM2 may have a multilayer structure. For example, the second semiconductor layer SEM2 may include an N−GaN layer and an N+GaN layer disposed on the N−GaN layer. The N+GaN layer may be a layer overdoped with a second conductivity type dopant. The N+GaN layer may increase the overall uniform luminescence of the light emitting element LE by lowering electrical resistance and improving current distribution when forming an ohmic electrode.

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (M g). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The protective film INS may be a film to protect the bottom and side surfaces of the light emitting element LE. The protective film INS may be disposed on the bottom and side surfaces of the conductive layer E1 and on the side surfaces of the semiconductor stack STC. For example, the protective film INS may be disposed on the bottom and side surfaces of the conductive layer E1, on the side surface of the first semiconductor layer SEM1, on the side surface of the active layer MQW, and on the side surface of the second semiconductor layer SEM2. The protective film INS may be formed of an inorganic film, for example, silicon nitride (SiNₓ), silicon oxide (SiON), silicon oxide (SiOₓ), titanium oxide (TiOₓ), and/or aluminum oxide (AlOₓ).

A hole LEH exposing the second semiconductor layer SEM2 may be formed through the conductive layer E1, the first semiconductor layer SEM1, and the active layer MQW of the light emitting element LE. The hole LEH may have a circular planar shape, but the embodiments of the present disclosure are not necessarily limited thereto. For example, the hole LEH may have a polygonal plan shape such as an elliptical shape, or a rectangular shape.

In addition, the protective film INS may be disposed on the sidewall of the conductive layer E1 exposed in the hole LEH, the sidewall of the first semiconductor layer SEM1, and the sidewall of the active layer MQW. The protective film INS might not cover the second semiconductor layer SEM2 in the hole LEH. Therefore, the second semiconductor layer SEM2 may be exposed without being covered by the protective film INS.

The first contact electrode CTE1 may be disposed on the lower surface of the conductive layer E1. For example, the first contact electrode CTE1 may be disposed on the exposed lower surface of the conductive layer E1 without being covered by the protective film INS. Therefore, the first contact electrode CTE1 may be electrically connected to the conductive layer E1.

The second contact electrode CTE2 may be disposed on the lower surface of the conductive layer E1. The second contact electrode CTE2 may be disposed on the protective film INS disposed in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

Each of the first contact electrode CTE1 and the second contact electrode CTE2 may include any one of molybdenum (Mo), aluminum (Al), chromium (Cr), gold (Au), titanium (Ti), nickel (Ni), neodymium (Nd), and copper (Cu). For example, each of the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

FIGS. 6 and 7 illustrate that the first contact electrode CTE1 and the second contact electrode CTE2 of each of the light emitting elements LE are disposed on the first organic layer 210, but the embodiment of the present disclosure is not necessarily limited thereto. For example, the first organic layer 210 may be disposed on a portion of the bottom surface and side surface of the first contact electrode CTE1 and a portion of the bottom surface and side surface of the second contact electrode CTE2 of each of the light emitting elements LE. Alternatively, the first organic layer 210 may be disposed on the side surfaces of the conductive layer E1 of each of the light emitting elements LE. Alternatively, the first organic layer 210 may be disposed on the side surfaces of the first semiconductor layer SEM1, the side surfaces of the active layer MQW, and the side surfaces of the second semiconductor layer SEM2 of each of the light emitting elements LE. In this case, the first organic layer 210 may be disposed on a portion of each side of the second semiconductor layer SEM2.

Each of the first contact electrode CTE1 and the second contact electrode CTE2 may be disposed on one side of the semiconductor stack STC, but the first contact electrode CTE1 and the second contact electrode CTE2 are disposed to be spaced apart from each other.

The first connection electrode CTEL1 may be disposed between the first contact electrode CTE1 and the first organic layer 210 and extend along the first organic layer 210 onto the pixel electrodes PXE1, PXE2, and PXE3. The first connection electrode CTEL1 connects the first contact electrode CTE1 of the light emitting element LE and the pixel electrodes PXE1, PXE2, and PXE3.

The second connection electrode CTEL2 may be disposed between the second contact electrode CTE1 and the first organic layer 210 and extend along the first organic layer 210 onto the common electrodes CE1, CE2, and CE3. The second connection electrode CTEL2 connects the second contact electrode CTE1 of the light emitting element LE and the common electrodes CE1, CE2, and CE3.

Each of the first connection electrode CTEL1 and the second connection electrode CTEL2 may include any of molybdenum (Mo), aluminum (Al), chromium (Cr), gold (Au), titanium (Ti), nickel (Ni), neodymium (Nd), and copper (Cu). For example, each of the first connection electrode CTEL1 and the second connection electrode CTEL2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

A first side electrode BE1 may be disposed on the top of the first connection electrode CTEL1 and on the side of the light emitting element LE. The first side electrode BE1 may be disposed on a portion of the side surface of the light emitting element LE. For example, the first side electrode BE1 may be disposed on a portion of the protective film INS of the light emitting element LE.

A second side electrode BE2 may be disposed on the top of the second connection electrode CT EL 2 and on the side of the light emitting element LE. The second side electrode BE2 may be disposed on a portion of the side surface of the light emitting element LE. For example, the second side electrode BE2 may be disposed on a portion of the protective film INS of the light emitting element LE.

Each of the first side electrode BE1 and the second side electrode B E2 may be disposed on a side of the light emitting element LE. Among the side surfaces of the light emitting element LE, an area adjacent to the top surface of the semiconductor stack STC may be exposed without being covered by the first side electrode BE1 and the second side electrode BE2. For example, the separation distance DS1 between the top surface of the light emitting element LE and the side electrodes BE1 and BE2 in the third direction DR3 may be greater than approximately 100 nm but is not necessarily limited thereto.

Each of the first side electrode BE1 and the second side electrode BE2 may include any one of molybdenum (Mo), aluminum (Al), chromium (Cr), gold (Au), silver (Ag), titanium (Ti), nickel (Ni), neodymium (Nd), and copper (Cu). Alternatively, each of the first side electrode BE1 and the second side electrode BE2 may be made of a transparent conductive material (TCO), such as indium tin oxide (ITO) and indium zinc oxide (IZO).

When each of the first side electrode BE1 and the second side electrode BE2 is made of a metal material with high reflectivity, light emitted from the active layer MQW of the light emitting element LE may be reflected from the first side electrode BE1 and the second side electrode BE2, and the light proceeding in the lateral direction of the light emitting element LE may proceed in the upward direction of the light emitting element LE. Accordingly, the light loss of the light emitting element LE may be reduced, and thus the light efficiency of the light emitting element LE may be increased.

Here, the third direction DR3 may be substantially the same as the height direction (or thickness direction) of the light emitting element LE. In this way, when the first side electrode BE1 and the second side electrode B E2 are spaced apart from the top surface of the light emitting element LE, a lateral leakage current that may occur on the upper side of the light emitting element LE may be prevented. When the first side electrode BE1 and the second side electrode BE2 are disposed up to the top surface of the light emitting element LE, the lateral leakage current may occur if the protective film INS is partially etched away by a subsequent process, causing the connection electrodes BE1 and BE2 to contact the semiconductor stack STC.

A first slope inclined layer SINS1 may surround the side surface of the light emitting element LE on the first side electrode BE1. Since the first slope inclined layer SINS1 is disposed on the first side electrode BE1, it might not be in contact with other components such as the light emitting element LE, the first organic layer 210, and the first contact electrode CTE1. The width of the first slope inclined layer SINS1 may be narrower as it goes upward, but the amount of decrease in width may be smaller as it goes upward. For example, the first slope inclined layer SINS1 may have a parabolic shape with the light emitting element LE disposed on the side and convex upward but is not necessarily limited to this.

Each of the first slope inclined layer SINS1 and the second slope inclined layer SINS2 may be an organic layer, such as an acrylic resin, an epoxy resin, a phenolic resin, a polyamide resin, a polyimide resin, or the like. Alternatively, each of the first slope inclined layer SINS1 and the second slope inclined layer SINS2 may be an inorganic layer, for example, silicon nitride (SiNₓ), silicon oxide (SiON), silicon oxide (SiOₓ), titanium oxide (TiOₓ), or aluminum oxide (AlOₓ). Alternatively, each of the first slope inclined layer SIN S1 and the second slope inclined layer SINS2 may be formed with an organic-inorganic hybrid composition.

The side surface of the light emitting element LE, the first side electrode BE1, and the first slope inclined layer SINS1 may have a concave structure in cross-section. For example, the concave structure may be a structure formed such that the separation distance DS1 between the top surface of the light emitting element LE and the first side electrode BE1 is farther than the separation distance DS2 between an extension of the top surface of the light emitting element LE and the first slope inclined layer SINS1. In this disclosure, “in cross-section” is defined as viewed in the first direction DR1 or the second direction DR2.

The second slope inclined layer SINS2 may surround the side surface of the light emitting element LE on the second side electrode BE2. Since the second slope inclined layer SINS2 is disposed on the second side electrode BE2, it might not be in contact with other components such as the light emitting element LE, the first organic layer 210, and the second contact electrode CTE2. The width of the second slope inclined layer SINS2 may be narrower as it goes upward, but the amount of decrease in width may be smaller as it goes upward. For example, the second slope inclined layer SIN S2 may have a parabolic shape with the light emitting element LE disposed on the side and convex upward but is not necessarily limited to this.

The side surface of the light emitting element LE, the second side electrode BE2, and the second slope inclined layer SIN S2 may have a concave structure in cross-section. For example, the concave structure may be a structure in which the separation distance DS2 between the top surface of the light emitting element LE and the second side electrode BE2 is formed at a greater distance than the separation distance DS2 between an extension of the top surface of the light emitting element LE and the second slope inclined layer SINS2.

A first dummy electrode DE 1 may be disposed on the first contact electrode CTE1, on at least a portion of the first pixel electrode PXE1 and on a side of the first organic layer 210. A first dummy inclined layer DINS1 may be disposed on the first dummy electrode DE1.

A second dummy electrode DE2 may be disposed on the second contact electrode CTE2, at least a portion of the first common electrode CE1 and on a side of the first organic layer 210. A second dummy inclined layer DINS2 may be disposed on the second dummy electrode DE2.

The width of each of the first dummy inclined layer DINS1 and the second dummy inclined layer DIN S2 may be narrower as it goes upward, but the amount of decrease in width may be smaller as it goes upward. For example, each of the first dummy inclined layer DINS1 and the second dummy inclined layer DIN S2 may have a convex shape with the light emitting element LE disposed on the side but are not necessarily limited thereto.

The first dummy inclined layer DINS1 and the second dummy inclined layer DINS2 are formed during the same process as the first slope inclined layer SINS1 and the second slope inclined layer SINS2, and are formed in the same manner, so they may include the same material. Therefore, each of the first dummy inclined layer DINS1 and the second dummy inclined layer DINS2 may be an organic layer, such as an acrylic resin, an epoxy resin, a phenolic resin, a polyamide resin, a polyimide resin, or the like. Alternatively, each of the first dummy inclined layer DINS1 and the second dummy inclined layer DIN S2 may be an inorganic layer, for example, silicon nitride (SiNₓ), silicon oxide (SiON), silicon oxide (SiOₓ), titanium oxide (TiOₓ), or aluminum oxide (AlOₓ). Alternatively, each of the first dummy inclined layer DINS1 and the second dummy inclined layer DINS2 may also be formed from an organic-inorganic hybrid composition.

The first dummy inclined layer DINS1 and the second dummy inclined layer DINS2 may be omitted.

A second organic film 211 may cover the plurality of light emitting elements LE. Further, the second organic film 211 may cover the first slope inclined layer SINS1, the second slope inclined layer SINS2, the first contact electrode CTE1, the second contact electrode CTE2, the first dummy inclined layer DINS1, and the second dummy inclined layer DINS2, but embodiments of the present disclosure are not necessarily limited thereto. In one example, the entire of the first slope inclined layer SINS1 and the second slope inclined layer SINS2 may be covered by the second organic film 211. The top surface of each of the plurality of light emitting elements LE may be exposed without being covered by the second organic film 211. In an example, the second organic film 211 may include a plurality of stacked organic films. The second organic film 211 is a layer for flattening the steps caused by the plurality of light emitting elements LE. When the height of the second organic film 211 covers most of the side surfaces of each of the plurality of light emitting elements LE, the second organic film 211 may be formed as a single layer.

The second organic film 211 may be formed from an organic film, such as an acrylic resin, an epoxy resin, a phenolic resin, a polyamide resin, a polyimide resin, or the like.

A first capping layer CAP1 may be disposed on the common electrode CE.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by the compartments the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM might not overlap the plurality of light emitting elements LE in the third direction DR3.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (e.g., light in the blue wavelength band) incident from the light emitting element LE into first light (e.g., light in the red wavelength band).

The second light conversion layer QDL2 may convert a portion of the third light (e.g., light in the blue wavelength band) incident from the light emitting element LE into second light (e.g., light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (e.g., light in the blue wavelength band) incident from the light emitting element LE into second light (e.g., light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The light blocking layer BM may include a first light blocking layer BM1 and a second light blocking layer BM2 that are sequentially stacked. A length of the first light blocking layer BM1 in the first direction DR1 or a length of the second direction DR2 may be wider than a length of the second light blocking layer BM2 in the first direction DR1 or a length of the second direction DR2 of the second light-receiving layer BM2. The first light blocking layer BM1 and the second light blocking layer BM2 may be formed of an organic film such as an acrylic resin, an epoxy resin, a phenolic resin, a polyamide resin, a polyimide resin, or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black or an organic black pigment.

The second capping layer CAP2 may be disposed on the first capping layer CAP1 and the light blocking layer BM. The second capping layer CAP2 may be disposed on the side and top surfaces of the light blocking layer BM. For example, the second capping layer CAP2 may be disposed on the side of the first light blocking layer BM1 and the side and top surfaces of the second light blocking layer BM2.

The reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on a second capture layer CAP2 disposed on the side of the first light blocking layer BM1 and the side of the second light blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material such as aluminum (Al). The thickness of the reflective film RF may be approximately 0.1 μm.

Alternatively, the reflective layer RF2 may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A fourth organic film 213 may be disposed on the second capping layer CAP2. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) that has been converted by the first light conversion layer QDL1 among the third light (e.g., light in the blue wavelength band) emitted from the light emitting element LE and absorb or block the third light (e.g., light in the blue wavelength band) that has not been converted by the first light conversion layer QDL1. Accordingly, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) that has been converted by the first light conversion layer QDL1 among the third light (e.g., light in the blue wavelength band) emitted from the light emitting element LE and absorb or block the third light (e.g., light in the blue wavelength band) that has not been converted by the first light conversion layer QDL1. Accordingly, the second sub-pixel SPX2 may emit the second light (e.g., light in the green wavelength band).

The third color filter CF3 disposed in the third sub-pixel SPX3 may transmit the third light (e.g., light in the blue wavelength band). Therefore, the third color filter CF3 may transmit the third light (e.g., light in the blue wavelength band) emitted from the light emitting element LE passing through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the light blocking layer BM in the third direction DR3.

A fifth organic film 214 may be disposed on the plurality of color filters CF1, CF2, and CF3 for planarization.

The fourth organic film 213 and the fifth organic film 214 may be formed from an acrylic resin, an epoxy resin, a phenolic resin, a polyamide resin, a polyimide resin, or the like.

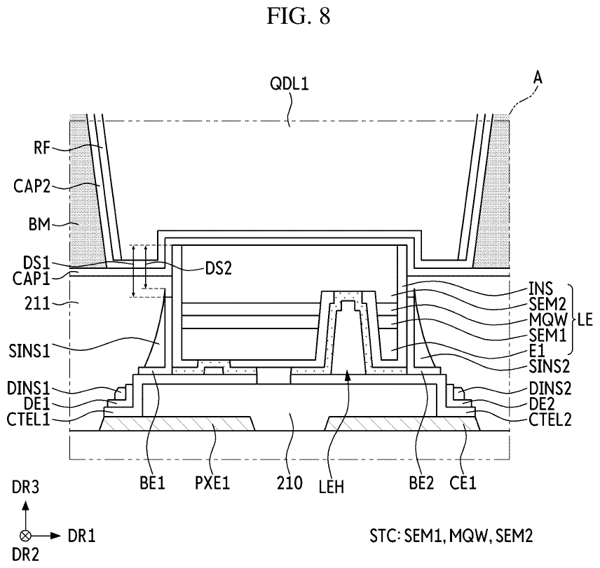

FIG. 8 is a cross-sectional view illustrating an example of area A1 in FIG. 6 in detail.

The embodiment of FIG. 8 is different from the embodiment of FIG. 7 in that the first slope inclined layer SINS1 and the second slope inclined layer SINS2 have a concave shape. In FIG. 8, descriptions overlapping with the embodiment of FIG. 7 will be omitted, and the description will focus on differences from the embodiment of FIG. 7. To the extent that an element is not described in detail with respect to this figure, it may be understood that the element is at least similar to a corresponding element that has been described elsewhere within the present disclosure.

Referring to FIG. 8, the first slope inclined layer SIN S1 may surround the side surface of the light emitting element LE on the first side electrode BE1. Since the first slope inclined layer SINS1 is disposed on the first side electrode BE1, it might not be in contact with other components such as the light emitting element LE, the first organic layer 210, and the first contact electrode CTE1. The width of the first slope inclined layer SINS1 may be narrower as it goes upward, but the amount of decrease in width may be smaller as it goes upward. For example, the first slope inclined layer SINS2 may have a parabolic shape with the light emitting element LE disposed on the side and concave downward but is not necessarily limited to this.

The second slope inclined layer SINS2 may surround the side surface of the light emitting element LE on the second side electrode BE2. Since the second slope inclined layer SINS2 is disposed on the second side electrode BE2, it might not be in contact with other components such as the light emitting element LE, the first organic layer 210, and the second contact electrode CTE2. The width of the second slope inclined layer SINS2 may be narrower as it goes upward, but the amount of decrease in width may increase as it goes upward. For example, the second slope inclined layer SINS2 may have a parabolic shape with the light emitting element LE disposed on the side and concave downward but is not necessarily limited to this.

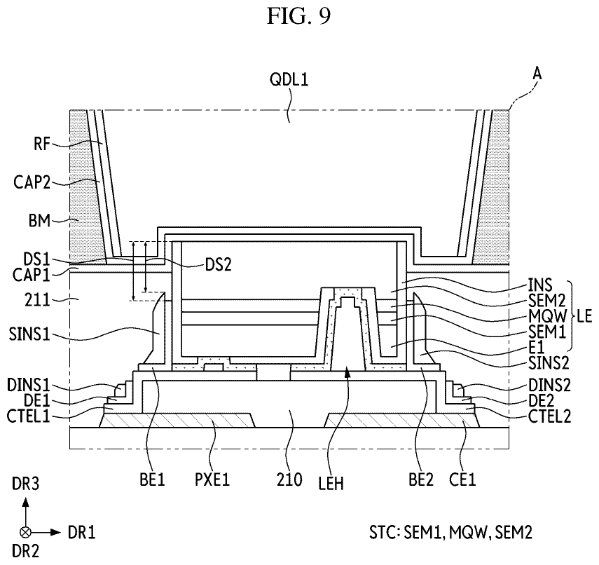

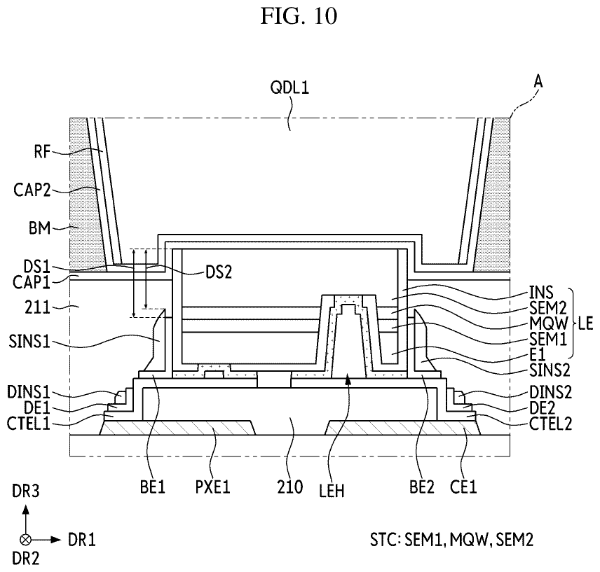

FIGS. 9 and 10 are cross-sectional views illustrating an example of area A1 in FIG. 6 in detail.

The embodiment of FIGS. 9 and 10 is different from the embodiment of FIG. 7 in that the first side electrode BE1 and the second side electrode BE2 do not cover the second semiconductor layer SEM2. In FIGS. 9 and 10, descriptions overlapping with the embodiment of FIG. 7 will be omitted, and the description will focus on differences from the embodiment of FIG. 7. Thus, to the extent that an element is not described in detail with respect to this figure, it may be understood that the element is at least similar to a corresponding element that has been described elsewhere within the present disclosure.

Referring to FIG. 9, each of the first side electrode BE1 and the second side electrode BE2 might not cover the second semiconductor layer SEM2. Each of the first side electrode BE1 and the second side electrode BE2 may be disposed up to the height of the boundary between the second semiconductor layer SEM2 and the active layer MQW.

Referring to FIG. 10, each of the first side electrode BE1 and the second side electrode BE2 might not cover the second semiconductor layer SEM2 and the active layer MQW. Each of the first side electrode BE1 and the second side electrode BE2 may be disposed up to the height of the boundary between the active layer MQW and the first semiconductor layer SEM1.

As shown in FIGS. 9 and 10, an area adjacent to the top surface of the semiconductor stack STC among the sides of the light emitting element LE may be exposed without being covered by the first side electrode BE1 and the second side electrode BE2. The exposed area that is not covered by the first side electrode BE1 and the second side electrode BE2 may fully or partially include the second semiconductor layer SEM2 and the active layer MQW. Regardless of the size of the exposed area, the light emitting element LE side, the first side electrode BE1, the first slope inclined layer SINS1, and the light emitting element LE side, the second side electrode BE2, and the second slope inclined layer SINS2 may have a concave structure in cross-section. For example, the concave structure may be a structure in which a separation distance DS1 between the top surface of the light emitting element LE and the first side electrode BE1 is formed farther than a separation distance DS2 between an extension of the top surface of the light emitting element LE and the first slope inclined layer SINS1. In addition, the separation distance DS1 between the top surface of the light emitting element LE and the second side electrode BE2 may be formed in a structure that is farther apart than the separation distance DS2 between an extension of the top surface of the light emitting element LE and the second slope inclined layer SINS2.

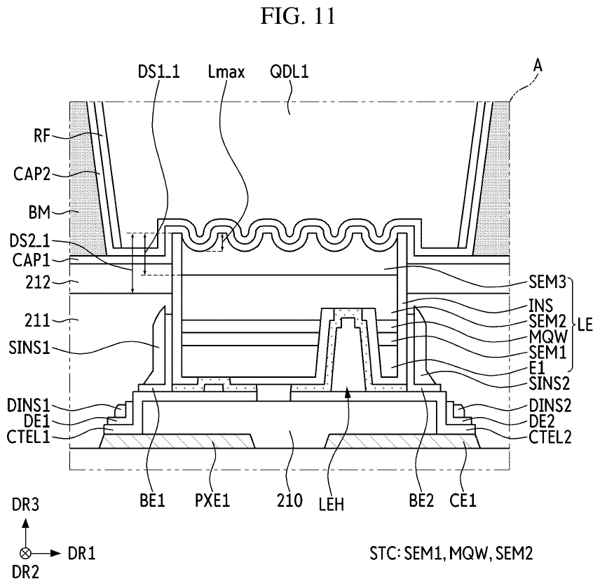

FIG. 11 is a detailed cross-sectional view illustrating an example of area A1 in FIG. 6.

The embodiment of FIG. 11 is different from the embodiment of FIG. 7 in that the semiconductor stack STC includes a third semiconductor layer SEM3 having a light extraction pattern LEP. In FIG. 11, descriptions overlapping with the embodiment of FIG. 7 will be omitted, and the description will focus on differences from the embodiment of FIG. 7. Thus, to the extent that an element is not described in detail with respect to this figure, it may be understood that the element is at least similar to a corresponding element that has been described elsewhere within the present disclosure.

Referring to FIG. 11, the semiconductor stack STC of the light emitting element LE may further include a third semiconductor layer SEM3. The third semiconductor layer SEM3 may be referred to as an un-doped semiconductor layer, which is a semiconductor material layer in which the n-type dopant is lower than a predetermined threshold value. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN), where the n-type dopant is below a predetermined threshold.

A light extraction patterns LEP may be formed on the top surface of the semiconductor stack STC. In one example, the light extraction patterns LEP may be formed on the top surface of the third semiconductor layer SEM3.

The light extraction patterns LEP may be patterns to increase the efficiency of light emitted from the top surface of the light emitting element LE. The light extraction patterns LEP may be a concave pattern formed as hemispheres or semi-ellipsoids. The light extraction patterns LEP may be a concave pattern with a semicircular or semi-elliptical cross-sectional shape. A maximum length L max of the light extraction patterns LEP in the third direction DR3 may be approximately 100 nm. Further, the distance between adjacent light extraction patterns LEP may be approximately 100 nm or less.

The light extraction patterns LEP may be formed from an organic film, such as an acrylic resin, epoxy resin, phenolic resin, polyamide resin, polyimide resin, or the like. Alternatively, the light extraction patterns LEP may be formed of an inorganic film, for example, silicon nitride (SiNₓ), silicon oxide (SiON), silicon oxide (SiOₓ), titanium oxide (TiOₓ), and/or aluminum oxide (AlOₓ).

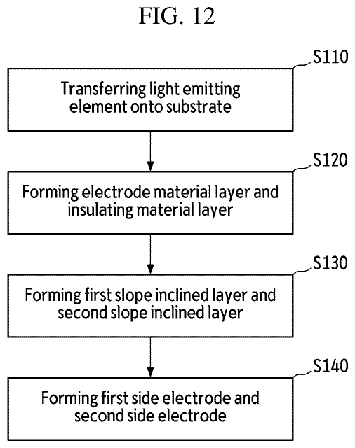

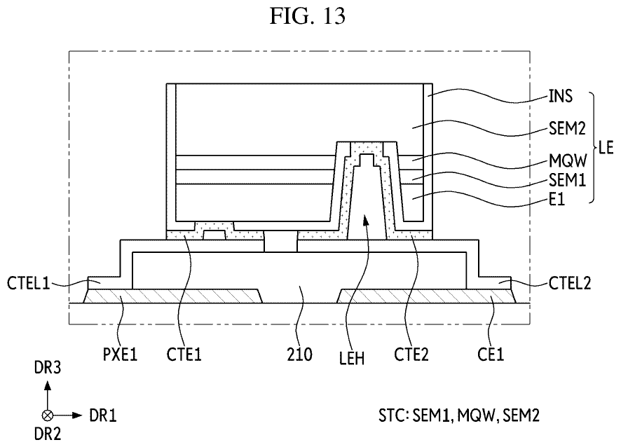

FIG. 12 is a flowchart illustrating a method of manufacturing a display device according to one embodiment. FIGS. 13 to 17 are example diagrams to illustrate a method of manufacturing a display device according to one embodiment.

Hereinafter, a method of manufacturing a display device according to one embodiment will be described in detail with reference to FIGS. 12 to 17. In FIGS. 13 to 17, cross-sections corresponding to one embodiment of FIG. 7 are shown for ease of description.

First, as shown in FIG. 13, the light emitting elements LE are transferred onto a substrate (SUB in FIG. 6) having a first connecting electrode CTEL1 and a second connecting electrode CTE2 disposed on a first organic layer 210 (S110 in FIG. 12).

Each of the plurality of light emitting elements LE may be formed by growing on a semiconductor substrate such as a silicon substrate or sapphire substrate. The plurality of light emitting elements LE may be transferred directly from the semiconductor substrate onto the pixel electrodes PXE1 of the display panel. Alternatively, the plurality of light emitting elements LE may be transferred onto the pixel electrodes PXE1 of the display panel by an electrostatic method using an electrostatic head or by a stamping method using an elastic polymeric material such as PDMS or silicon as a transfer substrate.

When the first organic layer 210 is a photosensitive organic film such as a photoresist, after hardening (soft baking) the first organic layer 210 at a first temperature, the first connection electrode CTEL1 and the second connection electrode CTE2 can be placed, and the first organic layer 210 may be fully cured at a second temperature higher than the first temperature. The first temperature may be approximately 100 degrees Celsius, and the second temperature may be approximately 230 degrees Celsius, but embodiments of the present disclosure are not necessarily limited thereto. Furthermore, the process of completely curing the first organic layer 210 at the second temperature may be performed for approximately 30 minutes.

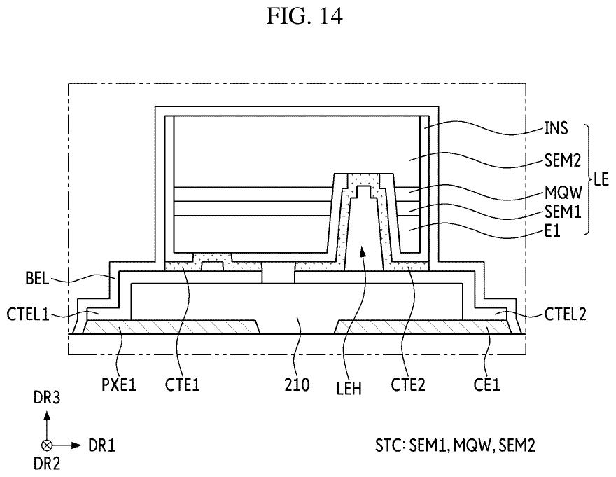

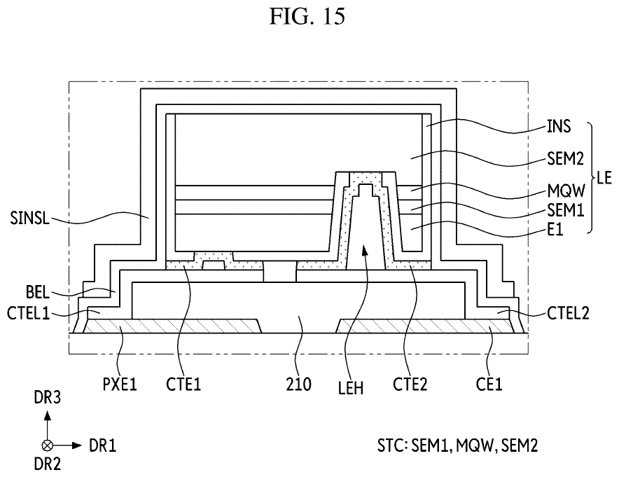

Second, as shown in FIGS. 14 and 15, an electrode material layer BEL and an insulating material layer SINSL are formed on the surface of the light emitting elements LE, the first connection electrode CTEL1 and the second connection electrode CTE2 (S120 in FIG. 12).

For example, the electrode material layer BEL may be entirely deposited on the second planarization organic film 180. The electrode material layer BEL may be formed to cover not only one surface and the side surface of the light emitting elements LE, but also the first connection electrode CTEL1 and the second connection electrode CTE2.

The insulating material layer SINSL is formed to completely cover the electrode material layer BEL. The insulating material layer SINSL may be formed thicker than the electrode material layer BEL. For example, the insulating material layer SINSL may be formed to a thickness of 3000 Å by depositing SiNₓ.

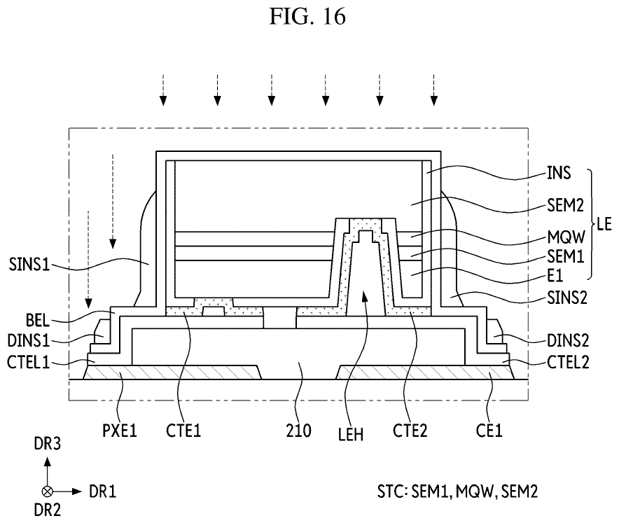

Third, as shown in FIG. 16, the insulating material layer SINSL is etched to form a first slope inclined layer SINS1 and a second slope inclined layer SINS2 (S130 in FIG. 12). The insulating material layer SINSL may be etched using a dry etching method. In the case of dry etching, anisotropic etching is possible and may be suitable for vertical etching. When using a dry etching method, the etching gas may be chlorine (Cl₂) or oxygen (O₂) gas but is not necessarily limited thereto. For example, a large voltage difference is created in the third direction DR3 without a separate mask, and the insulating material layer SINSL is etched using an etching gas. In this case, the etching gas moves in the third direction DR3 by voltage control, for example, moving from the top to the bottom, and can etch the insulating material layer SINSL. As a result, the insulating material layer SINSL disposed on the side of the light emitting element LE, the top surface of the first connection electrode CTEL1 adjacent to the side of the light emitting element LE, and the top surface of the second connection electrode CTEL2 adjacent to the side of the light emitting element LE may remain without being etched, even though it is not protected by the mask pattern.

Accordingly, a layer of insulating material SINSL disposed on the top of the light emitting element LE and on the top of the first connection electrode CTEL1 and the second connection electrode CTEL2 is etched. The insulating material layer SINSL disposed on the side of the light emitting element LE, the top surface of the first connection electrode CTEL1 adjacent to the side of the light emitting element LE, and the top surface of the second connection electrode CTEL2 adjacent to the side of the light emitting element LE may remain without being etched by anisotropic etching. Accordingly, the first slope inclined layer SINS1, the second slope inclined layer SINS2, the dummy inclined layer DIN S1, and the dummy inclined layer DINS2 are formed. Further, the insulating material layer SINSL disposed on the side of the first organic layer 210, the top surface of the first connection electrode CTEL1 adjacent to the side of the first organic layer 210, and the top surface of the second connection electrode CTEL2 adjacent to the side of the first organic layer 210 might not be etched by anisotropic etching. The height of the remaining insulating material layer SINLS may be adjusted by the concentration and time of the etching gas.

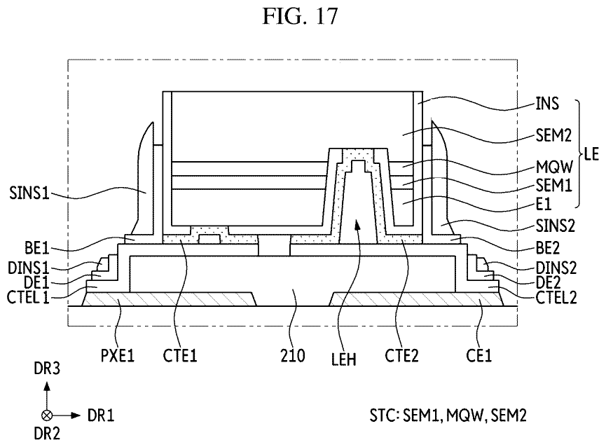

Fourth, as shown in FIG. 17, the electrode material layer BEL is etched to form the first side electrode BE1 and the second side electrode BE2 (S140 in FIG. 12).

The electrode material layer BEL is removed by etching the electrode material layer BEL exposed to the outside without the first slope inclined layer SIN S1, the second slope inclined layer SINS2, the dummy inclined layer DINS1 and the dummy inclined layer DINS2 being arranged by the wet etching method. Accordingly, the top surface of the light emitting element LE and the electrode material layer BEL on the side adjacent to the top surface of the light emitting element LE are removed. Furthermore, a portion of the top surfaces of the first side electrode BE1 and the second side electrode BE2 is removed to form the first dummy electrode DE1 and the second dummy electrode DE2.

The upper portion of the first side electrode BE1 between the light emitting element LE and the first slope inclined layer SINS1 may be depressed downward due to wet etching. Further, the top of the second side electrode BE2 between the light emitting element LE and the second slope inclined layer SINS2 may be depressed downward. For example, the separation distance DS1 between the top surface of the light emitting element LE and the side electrodes BE1 and BE2 may be longer than the separation distance DS2 between the top surface of the light emitting element LE and the first slope inclined layer SINS1 in the third direction DR3.

The first side electrode BE1, the second side electrode BE2, the first slope inclined layer SINS1, and the second slope inclined layer SINS2 formed in this way stably support the side surface of the light emitting element LE.

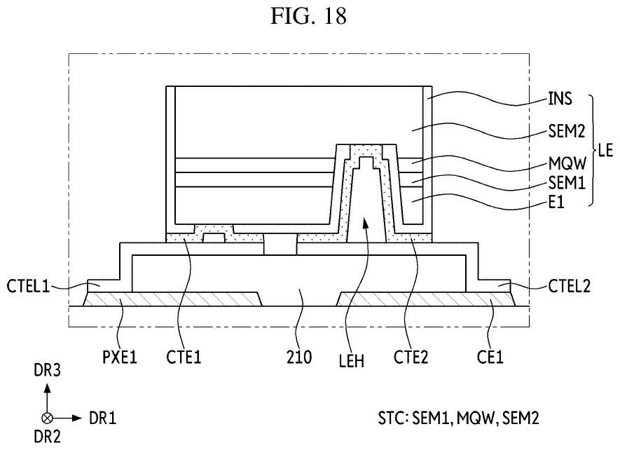

FIGS. 18 to 24 are example diagrams to illustrate a method of manufacturing a display device according to one embodiment.

Hereinafter, a method of manufacturing a display device according to one embodiment will be described in detail with reference to FIGS. 12 and 18 to 24. FIGS. 18 to 24 illustrate cross-sectional and perspective views corresponding to the embodiment of FIG. 8 for convenience of explanation.

First, as shown in FIG. 18, the light emitting elements LE are transferred onto a substrate (SUB in FIG. 6) having a first connection electrode CTEL1 and a second connection electrode CTE2 disposed on a first organic layer 210 (S110 in FIG. 12).

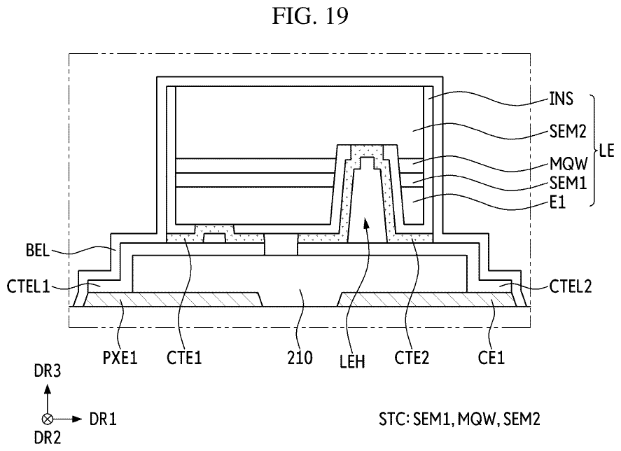

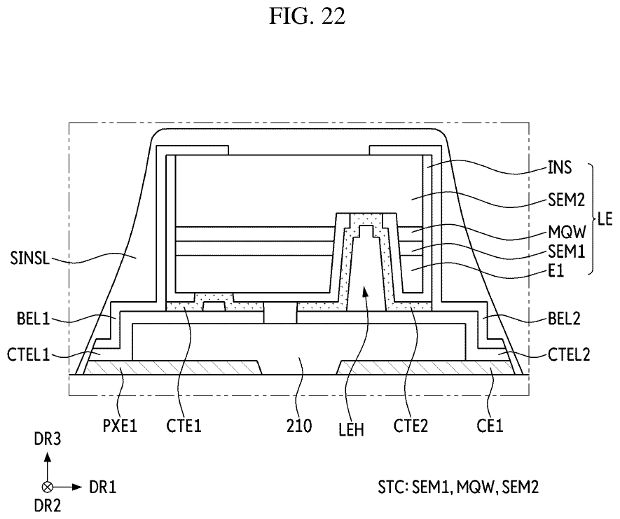

Second, as shown in FIGS. 19 and 22, an electrode material layer BEL and an insulating material layer SINSL are formed on the light emitting elements LE, the first connection electrode CTEL1, and the second connection electrode CTE2S120 in FIG. 12).

For example, as shown in FIG. 19, the electrode material layer BEL may be entirely deposited on the second planarization organic film 180. The electrode material layer BEL may be formed to cover not only one surface and the side surface of the light emitting elements LE, but also the first connection electrode CTEL1 and the second connection electrode CTE2.

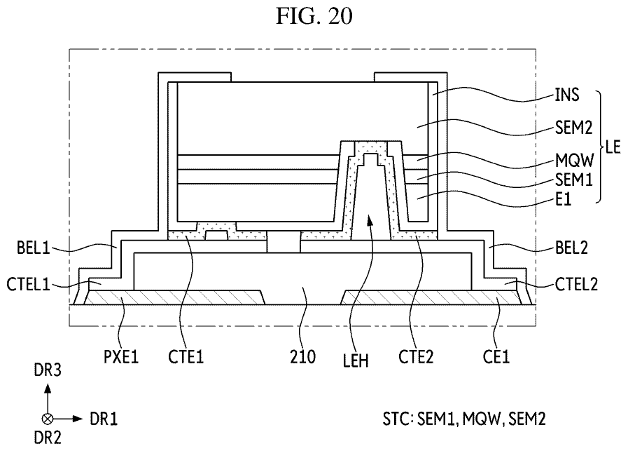

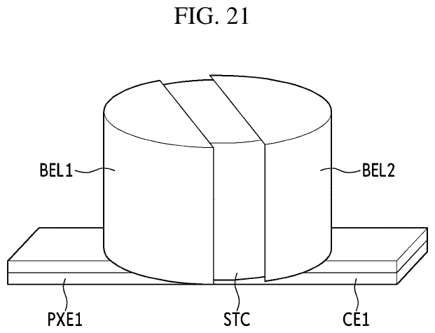

Next, as shown in FIGS. 20 and 21, the electrode material layer BEL is separated into two spaced apart first electrode material layers BEL1 and second electrode material layers BEL2 through an etching process using a photo mask. For example, the area protected by the photo mask may remain without being etched, and the area not protected by the photo mask may be etched. The photo mask may then be removed by an ashing process.

Next, the insulating material layer SINSL is formed to cover all the electrode material layers BEL1 and BEL2. The insulating material layer SINSL may be formed thicker than the electrode material layers BEL1 and BEL2. For example, the insulating material layer SINSL may be formed to a thickness of 3000 Å by depositing SiNₓ.

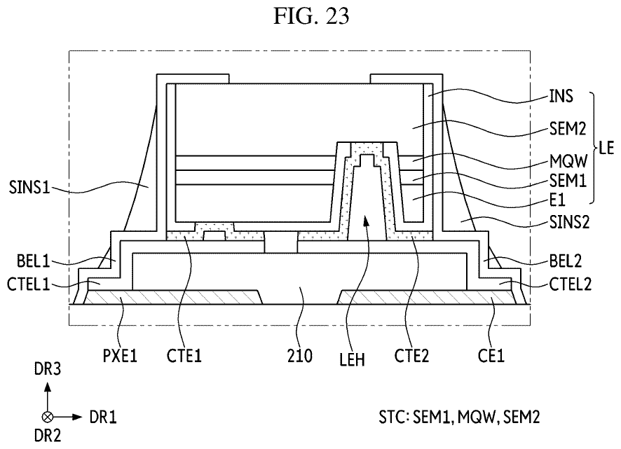

Third, as shown in FIG. 23, a portion of the insulating material layer SINSL is etched to form a first slope inclined layer SIN S1 and a second slope inclined layer SINS2 (S130 in FIG. 12). The insulating material layer SINSL may be etched by dry etching. In the case of dry etching, anisotropic etching is possible and may be suitable for vertical etching. When using a dry etching method, the etching gas may be chlorine (Cl₂) or oxygen (O₂) gas but is not necessarily limited thereto. For example, a large voltage difference is formed in the third direction DR3 without a separate mask, and the insulating material layer SIN SL is etched using an etching gas. In this case, the etching gas moves in the third direction DR3 by voltage control, for example, moving from the top to the bottom, and may etch the insulating material layer SINSL. Accordingly, the insulating material layer SINSL disposed on the light emitting element LE and on the first connection electrode CTEL1 and the second connection electrode CTEL2 is etched. An insulating material layer disposed on the side of the light emitting element LE, the top surface of the first connection electrode CTEL1 adjacent to the side of the light emitting element LE, and the top surface of the second connection electrode CTEL2 adjacent to the side of the light emitting element LE might not be etched by anisotropic etching. As a result, the first slope inclined layer SINS1, the second slope inclined layer SINS2, the dummy slope layer DINS1, and the dummy slope layer DINS2 are formed.

In addition, the insulating material layer SINSL disposed on the side of the first organic layer 210, the top surface of the first connection electrode CTEL1 adjacent to the side of the first organic layer 210, and the top surface of the second connection electrode CTEL2 adjacent to the side of the first organic layer 210 might not be etched by anisotropic etching. The height of the remaining insulating material layer SINLS may be adjusted by the concentration and time of the etching gas.

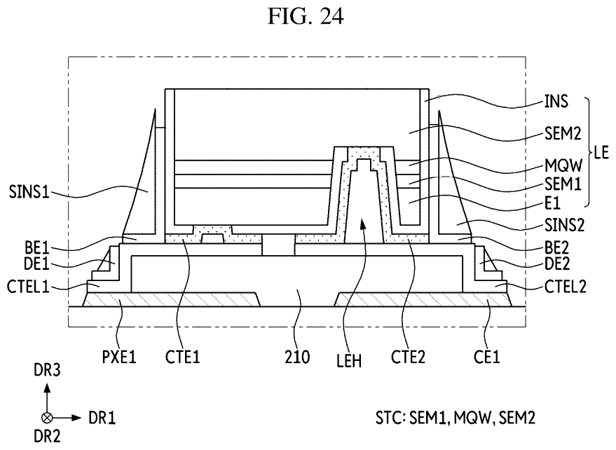

Fourth, as shown in FIG. 24, the electrode material layer BEL is etched to form the first side electrode BE1 and the second side electrode BE2 (S140 in FIG. 12).

The electrode material layer BEL is removed by etching the externally exposed electrode material layer BEL without the first slope inclined layer SIN S1, the second slope inclined layer SINS2, the dummy slope layer DINS1, and the dummy slope layer DINS2 being arranged by the wet etching method. Accordingly, the top surface of the light emitting element LE and the electrode material layer BEL on the side adjacent to the top surface of the light emitting element LE are removed. Furthermore, a portion of the top surfaces of the first side electrode BE1 and the second side electrode BE2 are removed to form the first dummy electrode DE1 and the second dummy electrode DE2.

The upper portion of the first side electrode BE1 between the light emitting element LE and the first slope inclined layer SINS1 may be sunken downward due to wet etching. Further, the top of the second side electrode BE2 between the light emitting element LE and the second slope inclined layer SINS2 may be depressed downward.

The first side electrode BE1, the second side electrode BE2, the first slope inclined layer SINS1, and the second slope inclined layer SINS2 formed in this way stably support the side surface of the light emitting element LE.

The light blocking layer, the wavelength conversion layer, the light transmission layer, and the color filter layer shown in FIG. 6 may be formed sequentially.

For example, referring to referring to FIG. 24 and FIG. 6, a first capping layer CAP1 is formed on the fourth organic film 213 and the light emitting elements LE, and a first light blocking layer BM1 and a second light blocking layer BM2 are formed on the first capping layer CAP1 so as not to overlap with the light emitting elements LE in the third direction DR3. Then, a second capping layer CAP2 is formed to cover the first light blocking layer BM1, the second light blocking layer BM2, and the first capping layer CAP1. Then, a reflective film RF is formed to cover the second capping layer CAP2 disposed on the first light blocking layer BM1 and the second light blocking layer BM2.

Then, a first light conversion layer QDL1 is formed in each of the first sub-pixels SPX1, a second light conversion layer QDL2 is formed in each of the second sub-pixels SPX2, and a light transmission layer TPL is formed on each of the third sub-pixels SPX3. Then, a third capping layer CAP3 is formed to cover the first light conversion layers QDL1, the second light conversion layers QDL2, and the light transmission layer TPL. Then, the fourth organic film 213 is formed on the third capping layer CPL3.

Then, a first color filter CF1 is formed on the fourth organic layer 213 to overlap the first light conversion layers QDL1 in the third direction DR3, a second color filter CF2 is formed that overlaps with the second light conversion layer QDL2 in the third direction DR3, and a third color filter CF3 is formed that overlaps with the light transmission layer TPL in the third direction DR3. The first color filter CF1, the second color filter CF2, and the third color filter CF3 may all be formed in the area overlapping the first light blocking layer BM1 and the second light blocking layer BM2 in the third direction DR3.

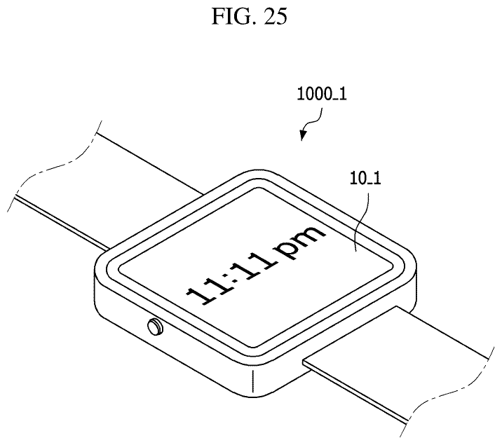

Then, the fifth organic film 214 is formed on the first color filter CF1, the second color filter CF2, and the third color filter CF3. FIG. 25 is an example view of a smart watch including a display device according to an embodiment.

Referring to FIG. 25, a display device 10_1 according to an embodiment may be applied to a smart watch 1000_1 which is one of smart devices.

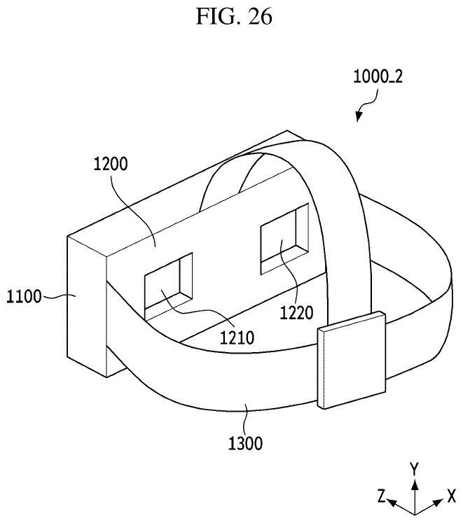

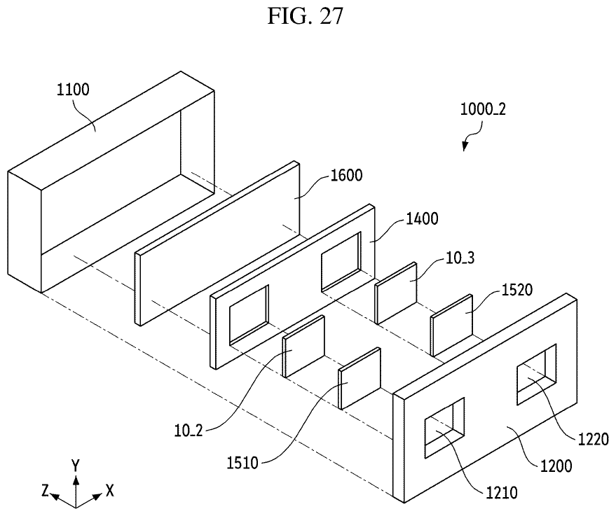

FIGS. 26 and 27 are example views of a virtual reality (VR) device including a display device according to an embodiment.

Referring to FIGS. 26 and 27, a head mounted display device 1000_2, according to an embodiment, includes a first display device 10_2, a second display device 10_3, a display device housing 1100, a housing cover 1200, a first eyepiece 1210, a second eyepiece 1220, a head mounted band 1300, a middle frame 1400, a first optical element 1510, a second optical element 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted. Thus, to the extent that an element is not described in detail with respect to this figure, it may be understood that the element is at least similar to a corresponding element that has been described elsewhere within the present disclosure.

The first optical element 1510 may be disposed between the first display device 10_2 and the first eyepiece 1210. The second optical element 1520 may be disposed between the second display device 10_3 and the second eyepiece 1220. Each of the first optical element 1510 and the second optical element 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical element 1510, the second optical element 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 26 and 27, embodiments of the present specification are not necessarily limited thereto. The first eyepiece 1210 and the second eyepiece 1220 may also be combined into one.

The first eyepiece 1210 may be aligned with the first display device 10_2 and the first optical element 1510, and the second eyepiece 1220 may be aligned with the second display device 10_3 and the second optical element 1520. Therefore, a user can view an image of the first display device 10_2, which is enlarged as a virtual image by the first optical element 1510, through the first eyepiece 1210 and can view an image of the second display device 10_3, which is enlarged as a virtual image by the second optical element 1520, through the second eyepiece 1220.

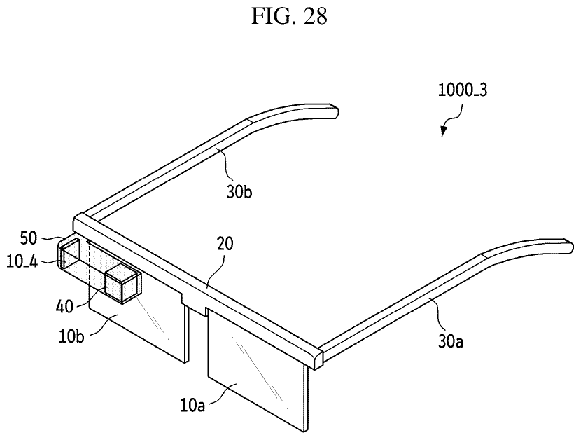

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 28 instead of the head mounted band 1300.

In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 28 is an example view of a VR device including a display device according to an embodiment. FIG. 28 illustrates a V R device 1000_3 to which a display device 10_4 according to an embodiment has been applied.

Referring to FIG. 28, the VR device 1000_3, according to an embodiment, may be a device in the form of glasses. The VR device 1000_3, according to the embodiment, may include the display device 10_4, a left lens 10a, a right lens 10b, a support frame 20, eyeglass frame legs 30a and 30b, a reflector 40, and a display device housing 50.

In FIG. 28, a case where the VR device 1000_3 is a glasses-type display device including the eyeglass frame legs 30a and 30b is illustrated as an example. For example, the VR device 1000_3 according to the embodiment is not necessarily limited to the one illustrated in FIG. 28 and can be applied in various forms to various other electronic devices.

The display device housing 50 may include the display device 10_4 and the reflector 40. An image displayed on the display device 10_4 may be reflected by the reflector 40 and provided to a user's right eye through the right lens 10b. Accordingly, the user may view a VR image displayed on the display device 10_4 through the right eye.

Although the display device housing 50 is disposed at a right end of the support frame 20 in FIG. 28, embodiments of the present specification are not necessarily limited thereto. For example, the display device housing 50 may also be disposed at a left end of the support frame 20. In this case, an image displayed on the display device 10_4 may be reflected by the reflector 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

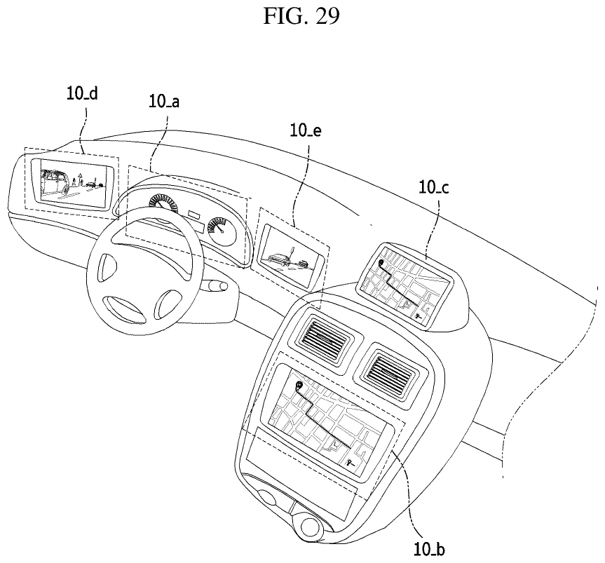

FIG. 29 is an example view illustrating a vehicle instrument cluster and center fascia including display devices according to an embodiment. FIG. 29 illustrates a vehicle to which display devices 10_a through 10_e according to an embodiment have been applied.

Referring to FIG. 29, the display devices 10_a through 10_c, according to the embodiment, may be applied to an instrument cluster of the vehicle, a center fascia of the vehicle, or a center information display (CID) disposed on a dashboard of the vehicle. In addition, the display devices 10_d and 10_e, according to the embodiment, may be applied to room mirror displays that replace side mirrors of the vehicle.

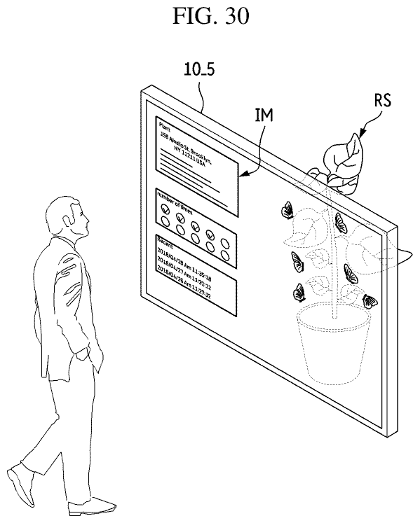

FIG. 30 is an example view of a transparent display device including a display device according to an embodiment.

Referring to FIG. 30, a display device 10_5, according to an embodiment, may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

In a display device and a method of manufacturing the same according to embodiments, a contact electrode of a light emitting element is spaced apart from an upper surface of a semiconductor stack. Therefore, the contact electrode exposed on the upper surface of the semiconductor stack can be prevented from being peeled off by a chemical solution or the like.

However, the effects of the present disclosure are not necessarily restricted to the one set forth herein. The above and other effects of the present disclosure will become more apparent to one of daily skill in the art to which the present disclosure pertains by referencing the claims.

What is claimed is:

1. A display device, comprising:
a substrate;
a pixel electrode and a common electrode disposed on the substrate;
an organic layer disposed on the pixel electrode and the common electrode;
a light emitting element disposed on the organic layer and including a semiconductor stack, a first contact electrode, and a second contact electrode, wherein the first and second contact electrodes are disposed on one surface of the semiconductor stack;
a first connection electrode connected to the first contact electrode and the pixel electrode;
a second connection electrode connected to the second contact electrode and the common electrode;
a first side electrode disposed on a first side of the light emitting element and a top surface of the first connection electrode;
a second side electrode disposed on a second side of the light emitting element and a top surface of the second connection electrode;
a first slope inclined layer disposed on a side surface of the first side electrode; and
a second slope inclined layer disposed on a side surface of the second side electrode,
wherein the first side electrode and the second side electrode have a downwardly concave structure between the first side of the light emitting element and the first slope inclined layer and between the second side of the light emitting element and the second slope inclined layer.

2. The display device of claim 1, wherein the concave structure is a structure in which a separation distance between a top surface of the light emitting element and the first side electrode is longer than a distance between an extension of the top surface of the light emitting element and the first slope inclined layer.

3. The display device of claim 1, wherein the light emitting element further comprises,
a conductive layer disposed between the organic layer and the semiconductor stack; and
a protective film disposed on at least one side of the conductive layer and sides of the semiconductor stack,
wherein the first contact electrode is disposed on the protective film and is connected to an exposed portion of the conductive layer that is not covered by the protective film, and
wherein the second contact electrode is disposed on the protective film and in a hole penetrating a portion of the conductive layer and the semiconductor stack.

4. The display device of claim 3, wherein the semiconductor stack further comprises:
a first semiconductor layer disposed on the organic layer and including a semiconductor material layer doped with a first conductivity type dopant;
an active layer disposed on the first semiconductor layer; and
a second semiconductor layer disposed on the active layer and including a semiconductor material layer doped with a second conductivity type dopant,
wherein a hole penetrating a portion of the semiconductor stack exposes the second semiconductor layer, and
wherein the second contact electrode is in contact with the exposed second semiconductor layer.

5. The display device of claim 4, wherein the first connection electrode is disposed between the first contact electrode and the organic layer and extends onto the pixel electrode on which the organic layer is not disposed and,
wherein the second connection electrode is disposed between the second contact electrode and the organic layer and extends onto a common electrode on which the organic layer is not disposed.

6. The display device of claim 4, wherein the first side electrode and the second side electrode are disposed on an entire side surface of the conductive layer and the first semiconductor layer and an entire side surface of the active layer, and on a portion of the side surface of the second semiconductor layer.

7. The display device of claim 4, wherein the first side electrode and the second side electrode are disposed on entire side surfaces of the conductive layer, the first semiconductor layer, and the active layer, and
wherein an entire side surface of the second semiconductor layer is exposed.

8. The display device of claim 4, wherein the first side electrode and the second side electrode are disposed on an entire side surface of the conductive layer and the first semiconductor layer and expose an entire side surface of the active layer and an entire side surface of the second semiconductor layer.

9. The display device of claim 4, wherein the semiconductor stack further comprises a third semiconductor layer disposed on the second semiconductor layer and containing a lower level of a second conductive dopant than the second semiconductor layer, and
wherein the third semiconductor layer further includes light extraction patterns formed in a concave cross-sectional shape on a top surface of the third semiconductor layer.

10. The display device of claim 1, wherein a width of each of the first slope inclined layer and the second slope inclined layer decreases upwardly, and an amount of decrease in width decreases or increases upwardly.

11. The display device of claim 1, further comprising a first dummy electrode disposed on a first side surface of the organic layer and on a top surface of the first connection electrode, and a second dummy electrode disposed on a second side surface of the organic layer and on a top surface of the second connection electrode.

12. The display device of claim 11, wherein the first connection electrode, the second connection electrode, the first dummy electrode, and the second dummy electrode include a same material.

13. The display device of claim 12, comprising a first dummy inclined layer disposed on a side surface and a top surface of the first dummy electrode, and a second dummy inclined layer disposed on a side surface and a top surface of the second side electrode.

14. The display device of claim 13, wherein the first slope inclined layer, the second slope inclined layer, the first dummy inclined layer, and the second dummy inclined layer include the same material.

15. A method of manufacturing a display device, comprising:
transferring light emitting elements including a first contact electrode and a second contact electrode disposed on one surface of a semiconductor stack onto a first connection electrode and a second connection electrode of a substrate;
sequentially forming an electrode material layer and an insulating material layer on a first connection electrode and a second connection electrode, in regions thereof where said light emitting elements are not disposed and are exposed;
forming a first slope inclined layer and a second slope inclined layer on a side surface of the light emitting elements by etching the insulating material layer; and
etching the electrode material layer to form a first side electrode and a second side electrode,
wherein the first side electrode and the second side electrode have a structure in which the first side electrode and the second side electrode are concave downward between a side surface of the light emitting elements and the first and second slope inclined layers.

16. The method of claim 15, wherein a pixel electrode and a common electrode are disposed on the substrate, and an organic layer is disposed on the pixel electrode and the common electrode,
wherein the first connection electrode is disposed on the pixel electrode and the organic layer, the second connection electrode is disposed on the common electrode and the organic layer, and
wherein the first connection electrode and the second connection electrode are spaced apart from each other.

17. The method of claim 15, wherein in the sequentially forming the electrode material layer and the insulating material layer, the insulating material layer completely covers the electrode material layer and is thicker than the electrode material layer.

18. The method of claim 15, wherein the insulating material layer is etched using a dry etching method, and
wherein the forming of the first slope inclined layer and the second slope inclined layer on the side surface of the light emitting element is performed on the electrode material layer,
wherein the forming of the first side electrode and the second side electrode comprises:
etching the electrode material layer by a wet etching method, and
wherein the first side electrode is formed on a first side of the light emitting elements and a top surface of the first connection electrode, and the second side electrode is formed on a second side of the light emitting elements and a top surface of the second connection electrode by removing the electrode material layer disposed on a portion of upper front and side surfaces of the light emitting elements.

19. The method of claim 16, wherein the forming the first side electrode and the second side electrode comprises:
etching the electrode material layer by a wet etching method, and
forming a first dummy electrode on a side of the organic layer where the insulating material layer is disposed and on a top surface of the first connection electrode, and forming a second dummy electrode on a side of the organic layer where the insulating material layer is disposed and on a top surface of the second connection electrode.

20. An electronic device comprising a display panel;
the panel comprises,
a substrate;
a pixel electrode and a common electrode disposed on the substrate;
an organic layer disposed on the pixel electrode and the common electrode;
a light emitting element disposed on the organic layer and including a semiconductor stack, a first contact electrode, and a second contact electrode, wherein the first and second contact electrodes are disposed on one surface of the semiconductor stack;
a first connection electrode connected to the first contact electrode and the pixel electrode;
a second connection electrode connected to the second contact electrode and the common electrode;
a first side electrode disposed on a first side of the light emitting element and a top surface of the first connection electrode;
a second side electrode disposed on a second side of the light emitting element and a top surface of the second connection electrode;
a first slope inclined layer disposed on a side surface of the first side electrode; and
a second slope inclined layer disposed on a side surface of the second side electrode,
wherein the first side electrode and the second side electrode have a downwardly concave structure between the first side of the light emitting element and the first slope inclined layer and between the second side of the light emitting element and the second slope inclined layer.
